(19) United States
(12) Patent Application Publication
(10) Pub. No.: US 2008/0238449 A1
(43) Pub. Date: Oct. 2, 2008

(54) Fluid sensor and impedance sensor

(75) Inventors: Atsuo Shizu, Ichinomiya-city (JP); Yasuaki Makino, Okazaki-city (JP); Takahiko Yoshida, Okazaki-city (JP); Tetsuo Yoshioka, Okazaki-city (JP); Kenji Fukumura, Kariya-city (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 12/073,816

(22) Filed: Mar. 11, 2008

(30) Foreign Application Priority Data
Mar. 27, 2007 (JP) 2007-81494
Sep. 4, 2007 (JP) 2007-229131

(51) Int. Cl. G01R 27/08; G01N 27/22

(52) U.S. Cl. 324/689; 73/335.04

(57) ABSTRACT

A fluid sensor detects property of fluid by dipping the sensor in the fluid. The sensor includes: a semiconductor substrate; and a comb-teeth electrode made of a first diffusion layer and disposed on a first surface of the substrate. Although the comb-teeth electrode is capable of directly contacting the fluid without a protection film, corrosion resistance of the sensor against the fluid is improved. Further, since the sensor has no protection film, the sensor can detect the property accurately.

### CROSS REFERENCE TO RELATED APPLICATIONS

This application is based on Japanese Patent Applications No. 2007-81494 filed on Mar. 27, 2007, and No. 2007-229131 filed on Sep. 4, 2007, the disclosures of which are incorporated herein by reference.

### FIELD OF THE INVENTION

The present invention relates to a fluid sensor and an impedance sensor.

### BACKGROUND OF THE INVENTION

The construction described in Patent Document 1 provides a known example of a sensor for detecting an alcohol content. This construction includes a casing having a channel for flowing fluid fuel and a sensor element provided in the casing so as to be exposed to an air-fuel mixture. However, the sensor according to the above-mentioned construction is large-sized. The sensor is mounted on a limited location and complicates a mounting structure.

As another example of solving such problem, there is known the semiconductor sensor (humidity sensor) described in Patent Document 2. The humidity sensor includes an insulating film and a humidity sensing film formed on a semiconductor substrate. A comb-like metal electrode such as aluminum or copper is formed on the film. A protective film (e.g., silicon nitride film) is formed on the metal electrode. When the semiconductor sensor according to this construction is used to detect a mixing rate of alcohol contained in the fluid fuel it can be used as a small-sized fluid nature sensor.

Patent Document 1: JP-H-5-507561 corresponding to U.S. Pat. No. 5,367,264

Patent Document 2: JP-2003-270189-A corresponding to U.S. Patent Application Publication No. 2003-0179805

The fluid fuel such as gasoline is remarkably corrosive to metals. When the semiconductor sensor is used as a fluid nature sensor, a corrosion protection film (e.g., silicon nitride film) needs to be formed on the comb-like metal electrode formed on the semiconductor substrate. However, increasing a permittivity difference between the protection film and a fluid to be detected decreases a capacitance change between the comb-like metal electrodes.

When the sensor is used for detecting the alcohol content in the fluid fuel (gasoline) for vehicles, it should be considered that a relative permittivity largely varies with the alcohol content. It is necessary to provide multiple protection films having different relative permittivities in order to improve the detection accuracy, i.e., to increase a capacitance change between electrodes. However, such construction complicates a signal processing circuit and a semiconductor manufacturing process.

Thus, It is required for a fluid nature sensor and an impedance sensor to have corrosion resistant while a fluid nature sensor's comb-like electrode is directly exposed to fluid.

### SUMMARY OF THE INVENTION

In view of the above-described problem, it is an object of the present disclosure to provide a fluid sensor and an impedance sensor.

According to a first aspect of the present disclosure, a fluid sensor detects property of fluid by dipping the sensor in the fluid. The sensor includes: a semiconductor substrate; and a comb-teeth electrode made of a first diffusion layer and disposed on a first surface of the substrate.

In the above sensor, although the comb-teeth electrode is capable of directly contacting the fluid without a protection film, corrosion resistance of the sensor against the fluid is improved. Further, since the sensor has no protection film, the sensor can detect the property accurately.

According to a second aspect of the present disclosure, a fluid sensor detects property of fluid by dipping the sensor in the fluid. The sensor includes: a semiconductor substrate; and a comb-teeth electrode made of poly silicon and disposed on a first surface of the substrate.

In the above sensor, although the comb-teeth electrode is capable of directly contacting the fluid without a protection film, corrosion resistance of the sensor against the fluid is improved. Further, since the sensor has no protection film, the sensor can detect the property accurately.

According to a third aspect of the present disclosure, an impedance sensor detects property of fluid or gas by arranging the sensor in the fluid or the gas. The sensor includes: a semiconductor substrate; and a comb-teeth electrode made of a first diffusion layer and disposed on a first surface of the substrate.

In the above sensor, although the comb-teeth electrode is capable of directly contacting the fluid without a protection film, corrosion resistance of the sensor against the fluid is improved. Further, since the sensor has no protection film, the sensor can detect the property accurately.

According to a fourth aspect of the present disclosure, an impedance sensor detects property of fluid or gas by arranging the sensor in the fluid or the gas. The sensor includes: a semiconductor substrate; and a comb-teeth electrode made of poly silicon and disposed on a first surface of the substrate.

In the above sensor, although the comb-teeth electrode is capable of directly contacting the fluid without a protection film, corrosion resistance of the sensor against the fluid is improved. Further, since the sensor has no protection film, the sensor can detect the property accurately.

### BRIEF DESCRIPTION OF THE DRAWINGS

The above and other objects, features and advantages of the present invention will become more apparent from the following detailed description made with reference to the accompanying drawings. In the drawings:

FIG. 1 is a longitudinal sectional view of a fluid nature sensor according to a first embodiment of the invention;

FIG. 2 is a top view of the fluid nature sensor;

FIG. 3 is a graph showing relation between a fluid blend ratio and a capacitance value;

FIG. 4 is a partial top view of a fluid nature sensor according to a second embodiment of the invention;

FIG. 5 is a longitudinal sectional view of a fluid nature sensor according to a third embodiment of the invention;

FIG. 6 is a longitudinal sectional view of a fluid nature sensor according to a fourth embodiment of the invention;

FIG. 7 is a longitudinal sectional view of a fluid nature sensor according to a fifth embodiment of the invention;

FIG. 8 is a longitudinal sectional view of a fluid nature sensor according to a sixth embodiment of the invention;

FIG. 9 is a perspective view of a fluid nature sensor according to a seventh embodiment of the invention;

FIG. 10 is a longitudinal sectional view of a fluid nature sensor according to an eighth embodiment of the invention;

FIG. 11 is a longitudinal sectional view of a fluid nature sensor according to a ninth embodiment of the invention;

FIG. 12 is a longitudinal sectional view of a fluid nature sensor according to a tenth embodiment of the invention;

FIG. 13 is a top view of the fluid nature sensor shown in FIG. 12;

FIG. 14 is a longitudinal sectional view of a fluid nature sensor according to an eleventh embodiment of the invention;

FIG. 15 is a partial top view of a fluid nature sensor according to a twelfth embodiment of the invention;

FIG. 16 is a longitudinal sectional view of the fluid nature sensor shown in FIG. 15;

FIG. 17 is a top view of a fluid nature sensor according to a thirteenth embodiment of the invention;

FIG. 18 is a longitudinal sectional view of a fluid nature sensor according to a fourteenth embodiment of the invention;

FIG. 19 is a longitudinal sectional view of a fluid nature sensor according to a fifteenth embodiment of the invention;

FIG. 20 is a longitudinal sectional view of a fluid nature sensor according to a sixteenth embodiment of the invention; and

FIG. 21 is a longitudinal sectional view of a fluid nature sensor according to a seventeenth embodiment of the invention.

### DETAILED DESCRIPTION OF THE PREFERRED EMBODIMENTS

### First Embodiment

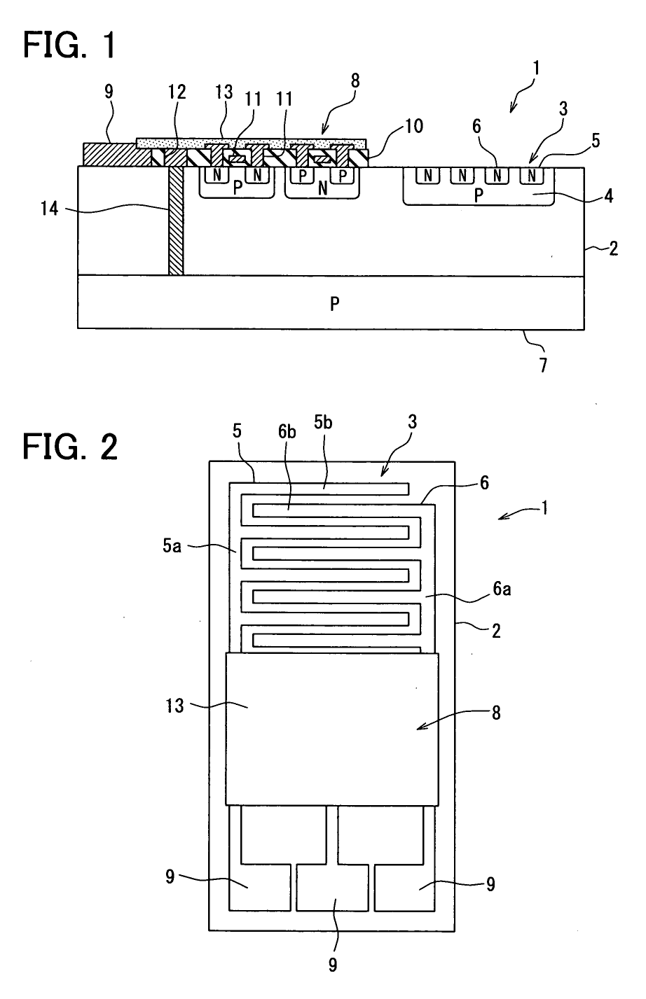

A first embodiment of the invention will be described with reference to FIGS. 1 through 3. FIG. 1 is a longitudinal sectional view showing an overall construction of a fluid nature sensor 1 according to the embodiment. The fluid nature sensor 1 detects a blend ratio of alcohol contained in the vehicle's fluid fuel such as gasoline. The fluid nature sensor 1 uses a semiconductor sensor. The fluid nature sensor detects a blend ratio etc. of alcohol contained in fluid fuel such as gasoline as a blend ratio etc. of fluid or gas.

As shown in FIG. 1, the fluid nature sensor 1 includes, for example, a semiconductor substrate 2 using an Si substrate and a sensor section 3 that is made of a diffuse layer and is provided on the first surface of the semiconductor substrate 2 at the right in FIG. 1. The sensor section includes a P layer 4 and comb-like electrodes 5 and 6. The P layer 4 is formed on the surface of the semiconductor substrate 2. The comb-like electrodes 5 and 6 are made of an N layer formed on the P layer 4. The comb-like electrodes 5 and 6 are formed as shown in FIG. 2. The comb-like electrodes 5 and 6 include a pair of common sections 5a and 6a and many comb tooth sections 5b and 6b projecting from the common sections 5a and 6a. The comb tooth sections 5b and 6b engage with each other at a specified interval.

Only the sensor section 3 on the semiconductor substrate 2 is dipped in and directly exposed to a fluid fuel to be measured. In this case, a capacitance is stored between the comb tooth sections 5b and 6b. The capacitance corresponds to a permittivity of the targeted fluid fuel.

A P-type diffuse layer 7 is formed on an entire second surface of the semiconductor substrate 2. The diffuse layer 7 is not necessarily formed on the entire rear surface thereof, but just needs to be formed correspondingly to the sensor section 3 (comb-like electrodes 5 and 6) on the rear surface of the semiconductor substrate 2, i.e., to the right of FIG. 1.

A signal processing circuit 8 and three pads 9, for example, are formed on the first surface of the semiconductor substrate 2 at the bottom of FIG. 2 (to the left of FIG. 1). The signal processing circuit 8 connects with the comb-like electrodes 5 and 6 and the three pads 9. The signal processing circuit 8 includes devices such as CMOS transistors and capacitors. These devices are used to construct a C/V conversion circuit for converting a capacitance value into a voltage value, a filter circuit for eliminating noise components, a sample hold circuit for sample-holding voltage values at a specified cycle, and an amplification circuit for amplifying a voltage value output from the sample hold circuit. The signal processing circuit 8 further includes a processing circuit that detects a fluid fuel temperature and corrects the relation between blend ratio and capacitance values in accordance with the temperature. A signal output from the signal processing circuit 8 is output outside via one of the three pads 9. Of the two remaining pads 9, one is used for a ground and the other is used for a power supply. As shown in FIG. 1, the signal processing circuit 8 includes an inter-layer insulating film 10, a wiring layer 11, a ground electrode 12, and a protection film 13.

A lead-through electrode 14 is provided so as to pierce through the semiconductor substrate 2. The lead-through electrode 14 connects the ground electrode 12 with the diffuse layer 7 on the second surface of the semiconductor substrate 2. The lead-through electrode 14 is made of a diffuse layer, for example.

Let us consider a case of using above-mentioned fluid nature sensor 1 to detect a blend ratio of alcohol contained in the vehicle's fluid fuel (gasoline). The fluid nature sensor 1 is placed in a special sensor case. Only the sensor section 3 of the fluid nature sensor 1 is protruded toward the outside. In this manner, only the sensor section 3 is dipped in and directly exposed to the fluid fuel to be measured. The other parts of the fluid nature sensor 1 do not contact the fluid fuel.

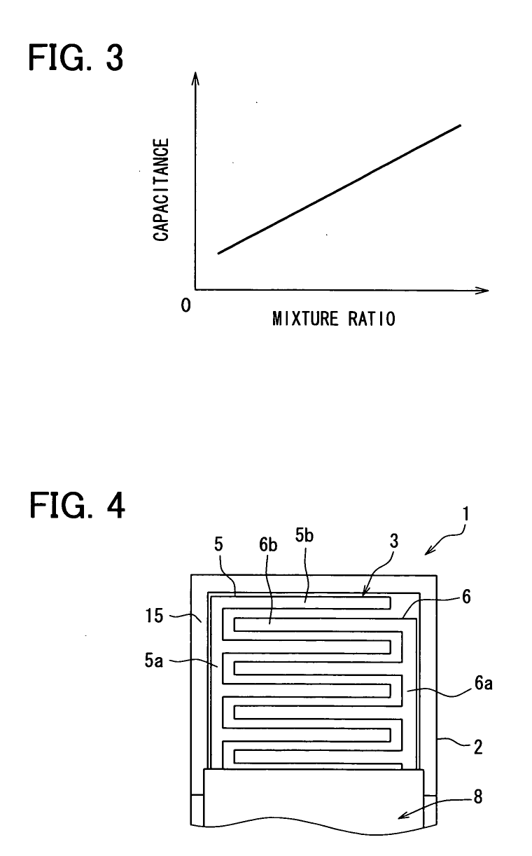

A blend ratio of alcohol contained in the vehicle's fluid fuel may be detected from a capacitance value (in accordance with the fluid fuel permittivity) between the comb tooth sections 5b and 6b of the comb-like electrodes 5 and 6 in the sensor section 3 as follows. For this purpose, a graph (data) as shown in FIG. 3 represents the relation between blend ratio (i.e., mixture ratio of fluid) and capacitance values for the fluid fuel (gasoline and alcohol). The graph is created and stored beforehand. It is possible to find a blend ratio corresponding to a capacitance value that is measured based on the graph. The relative permittivity of the fluid fuel (gasoline and alcohol) varies with temperature. It is preferable to detect the fluid fuel temperature and make correction based on the temperature. The diffuse layer can resist corrosion because the above-mentioned fluid nature sensor 1 is provided with the comb-like electrodes 5 and 6 made of the diffuse layer on the first surface of the semiconductor substrate 2. The full corrosion resistance can be ensured by directly exposing the comb-like electrodes 5 and 6 to the fluid fuel, i.e., eliminating the protection film. Differently from the prior construction (Patent Document 2), the above-mentioned fluid nature sensor 1 uses no protection film and can highly accurately detect a blend ratio (fluid nature). Since no protection film is formed, the number of manufacturing processes can be decreased to reduce manufacturing costs accordingly.

The embodiment provides the diffuse layer 7 for the entire rear surface of the semiconductor substrate 2 and can ensure the construction hardly subject to adverse effects such as an electromagnetic noise. The lead-through electrode 14 is provided so as to pierce the semiconductor substrate 2 and provides connection between the ground electrode 12 on the first surface of the semiconductor substrate 2 with the diffuse layer 7 on the rear surface thereof. The fluid fuel may be electrically charged while flowing through pipes. The static electricity can be discharged to the ground electrode 12 via the diffuse layer 7 and the lead-through electrode 14 on the rear surface. This makes it possible to decrease a detection error in the blend ratio detected by the comb-like electrodes 5 and 6. In addition, it is possible to prevent foreign material from being attached and protect the signal processing circuit 8 against electrostatic breakdown.

According to the embodiment, the fluid nature sensor 1 and the signal processing circuit 8 are integrally provided on the semiconductor substrate 2 and can provide a so-called one-chip construction. The overall sensor construction can be more miniaturized.

The embodiment directly applies a voltage between the comb-like electrodes 5 and 6 to construct a direct current drive system. Instead, an alternate current drive system may be constructed. According to this construction, an ion contained in an object to be measured such as the fluid fuel adheres to or collects near surfaces of the comb-like electrodes 5 and 6. An electric current flows between the comb-like electrodes 5 and 6 through the ion, preventing the signal processing circuit 8 from being destroyed due to short-circuiting.

In the embodiment, it is preferable to apply a forward bias voltage to the N layer and a reverse bias voltage to the P layer of the comb-like electrodes 5 and 6. This construction can increase an internal voltage and especially prevent a current leak from a PN bonded interface at a high temperature.

The first embodiment may measure not only the capacitance but also the impedance including an electric conductivity and a dielectric loss. Simultaneously measuring multiple physical values can improve the measurement accuracy, determine introduction of foreign material, and correct errors.

FIG. 4 shows a second embodiment of the invention. The mutually corresponding parts in FIGS. 2 and 1 are designated by the same reference numerals. The second embodiment forms a diffuse layer 15 not only on the second surface of the semiconductor substrate 2 but also on the first surface thereof, specifically around the comb-like electrodes 5 and 6. The other portions of the construction according to the second embodiment are the same as the first embodiment.

The second embodiment can provide almost the same effect as the first embodiment. In particular, the diffuse layer 15 according to the second embodiment works as a guard ring, making it possible to further decrease adverse effects such as static electricity and electromagnetic noise. The second embodiment may not form the diffuse layer 7 on the second surface of the semiconductor substrate 2 or may form the diffuse layer 15 only on the first surface of the semiconductor substrate 2.

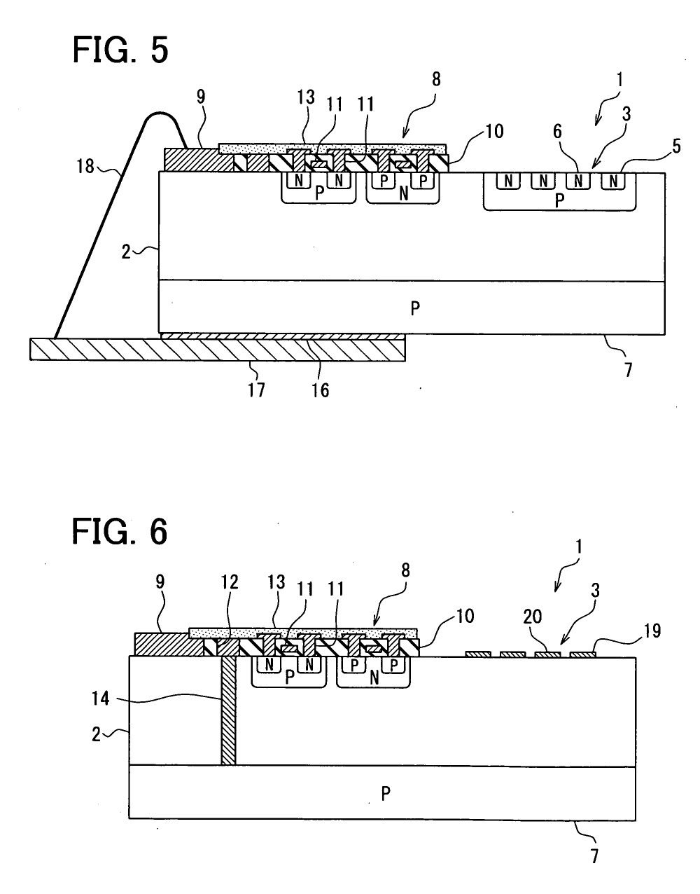

FIG. 5 shows a third embodiment of the invention. The mutually corresponding parts in FIGS. 3 and 1 are designated by the same reference numerals. The third embodiment forms a metal film 16 such as aluminum or copper on the diffuse layer 7 on the second surface of the semiconductor substrate 2. A lead frame 17 is bonded to the metal film 16 through the use of soldering or a conductive adhesive. A wire 18 is used for wire bonding between the lead frame 17 and the pad 9 for the ground provided on the first surface of the semiconductor substrate 2.

The other portions of the construction according to the third embodiment are the same as the first embodiment. Therefore, the third embodiment can provide almost the same effect as the first embodiment. The third embodiment can ensure a wide ground contact area, making it possible to further decrease adverse effects such as static electricity and electromagnetic noise. The wire bonding can simplify processes in comparison with the use of the lead-through electrode.

FIG. 6 shows a fourth embodiment of the invention. The mutually corresponding parts in FIGS. 6 and 1 are designated by the same reference numerals. The fourth embodiment uses comb-like electrodes 19 and 20 made of corrosion-resistant silicon. That is, the polysilicon comb-like electrodes 19 and 20 are formed on the first surface of the semiconductor substrate 2. The comb-like electrodes 19 and 20 are shaped equally to the comb-like electrodes 5 and 6 according to the first embodiment.

The other portions of the construction according to the fourth embodiment are the same as the first embodiment. Therefore, the fourth embodiment can provide almost the same effect as the first embodiment.

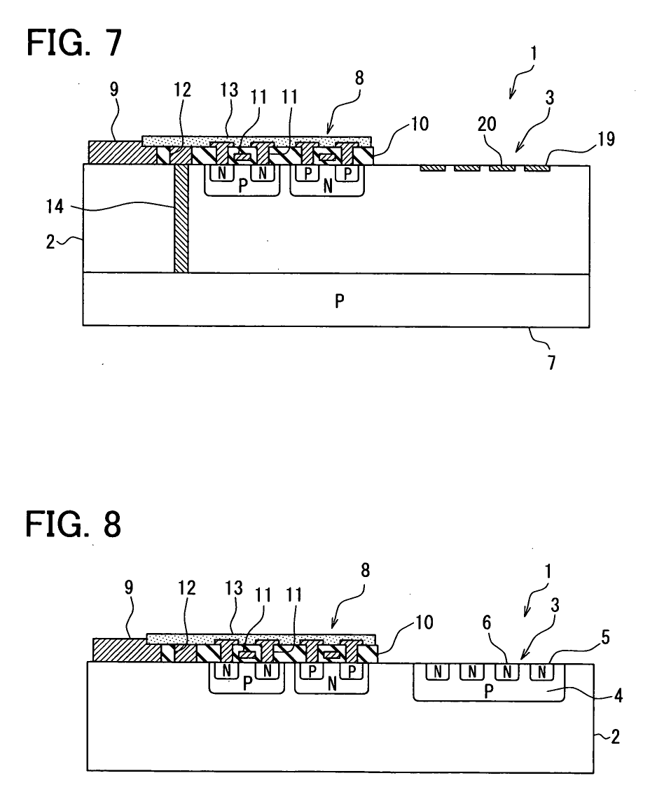

FIG. 7 shows a fifth embodiment of the invention. For example, the CMP technology is used to embed the polysilicon comb-like electrodes 19 and 20 in the semiconductor substrate 2. The detection section can be free from unevenness and can be protected against adhesion of foreign material (contaminant components) in the blended fuel. Accordingly, the detection accuracy can be prevented from being degraded. The other portions of the construction according to the fifth embodiment are the same as the fourth embodiment.

FIG. 8 shows a sixth embodiment of the invention. The mutually corresponding parts in FIGS. 8 and 1 are designated by the same reference numerals. The sixth embodiment forms neither the diffuse layer 7 on the second surface of the semiconductor substrate 2 nor the lead-through electrode 14. The other portions of the construction according to the sixth embodiment are the same as the first embodiment. Therefore, the sixth embodiment can provide almost the same effect as the first embodiment.

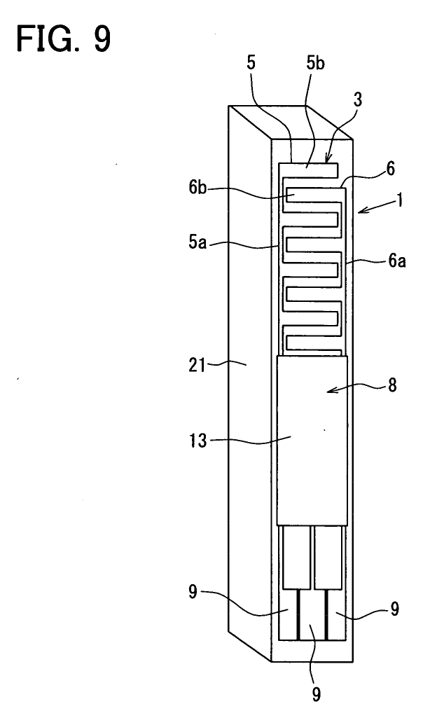

FIG. 9 shows a seventh embodiment of the invention. The mutually corresponding parts in the seventh and first embodiments are designated by the same reference numerals. A semiconductor substrate 21 according to the seventh embodiment is shaped into a long and thin chip. It is preferable that a cross section of the semiconductor substrate 21 is almost square or rectangular. The other portions of the construction according to the seventh embodiment are the same as the first embodiment.

Therefore, the seventh embodiment can provide almost the same effect as the first embodiment. In particular, only the sensor section 3 can be easily exposed to the fluid because the semiconductor substrate 21 according to the seventh embodiment is shaped into a long and thin chip.

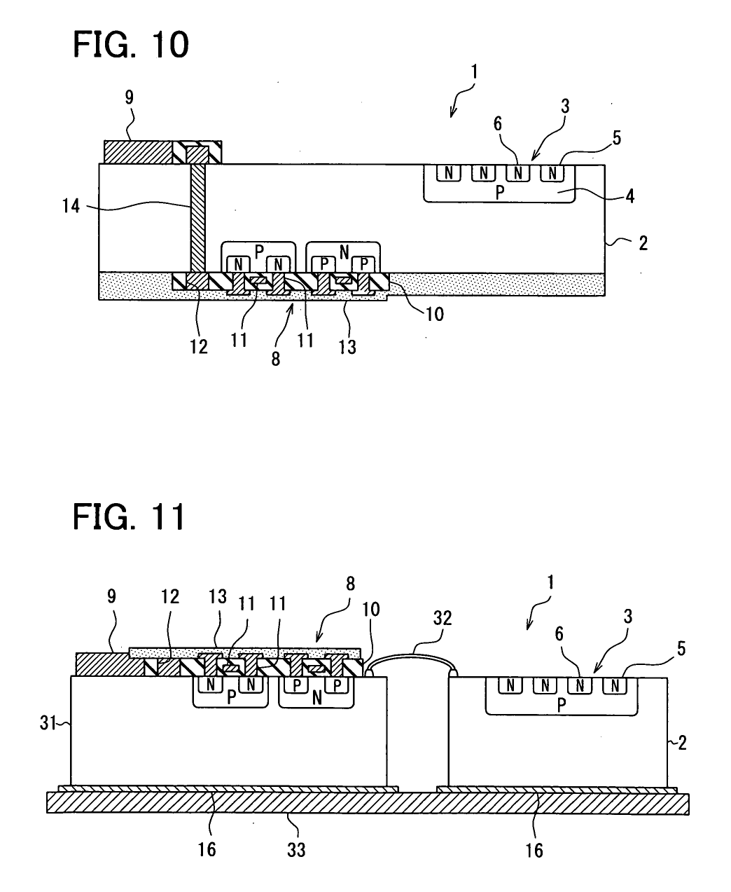

FIG. 10 shows an eighth embodiment of the invention. The mutually corresponding parts in FIGS. 10 and 1 are designated by the same reference numerals. The eighth embodiment provides the signal processing circuit 8 on the second surface (bottom surface) of the semiconductor substrate 2. The lead-through electrode 14 connects the pad 9 on the first surface of the semiconductor substrate 2 with the ground electrode 12 of the signal processing circuit 8. The protection film 13 coverts the bottom surface (second surface of the semiconductor substrate 2) of the signal processing circuit 8.

The other portions of the construction according to the eighth embodiment are the same as the first embodiment. Therefore, the eighth embodiment can provide almost the same effect as the first embodiment. The eighth embodiment can further miniaturize the entire sensor chip using the construction as shown in FIG. 10. Only the sensor section is exposed to the fluid fuel. The signal processing circuit 8 is not directly exposed to the fuel. The embodiment can prevent the circuit from being corroded and improve the reliability.

FIG. 11 shows a ninth embodiment of the invention. The mutually corresponding parts in the ninth and first embodiments are designated by the same reference numerals. The ninth embodiment provides the signal processing circuit 8 on a semiconductor substrate 31 different from the semiconductor substrate 2 provided with the comb-like electrodes 5 and 6. A wire 32 is used for wire bonding between the signal processing circuit 8 and the comb-like electrodes 5 and 6. The two semiconductor substrates 2 and 31 are fastened to a lead frame by soldering, for example. The metal film 16 is formed on second surfaces of the semiconductor substrates 2 and 31.

The other portions of the construction according to the ninth embodiment are the same as the first embodiment. Therefore, the ninth embodiment can provide almost the same effect as the first embodiment. According to the construction as shown in FIG. 11, the ninth embodiment can manufacture the sensor section 3 and the signal processing circuit 8 in different processes, easily improving a yield ratio and ensuring the quality.

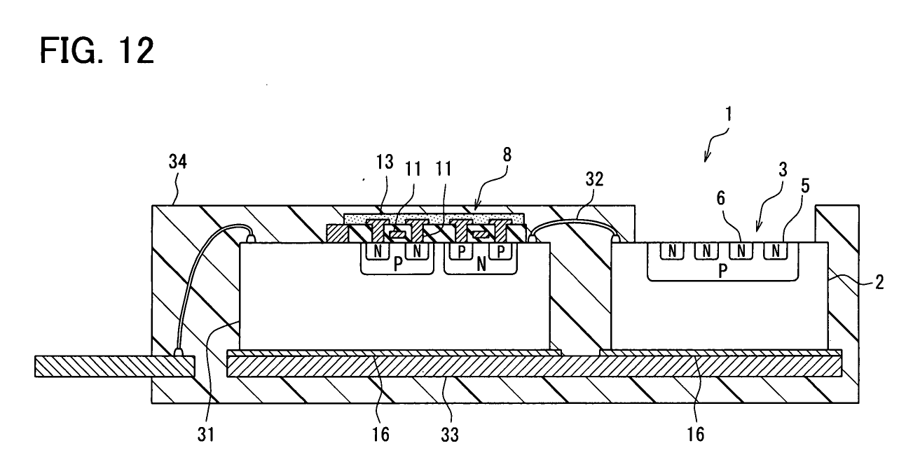

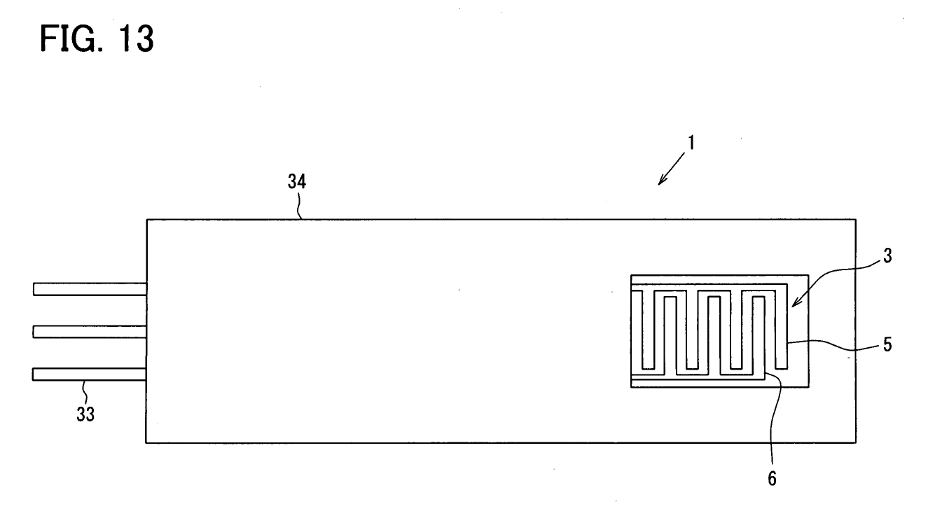

FIGS. 12 and 13 show a tenth embodiment of the invention. The mutually corresponding parts in the tenth and ninth embodiments are designated by the same reference numerals. The semiconductor substrate 31 is provided with the signal processing circuit 8. The semiconductor substrate 2 is provided with the comb-like electrodes 5 and 6. The tenth embodiment fastens the semiconductor substrates 31 and 2 to the lead frame 33. A resin (e.g., epoxy resin) 34 is used to mold the lead frame 33 along with the semiconductor substrates 31 and 2 so as to expose the comb-like electrodes 5 and 6. The other portions of the tenth construction are almost the same as the ninth embodiment. Therefore, the tenth embodiment can provide almost the same effect as the ninth embodiment. The tenth embodiment exposes only the sensor section 3 according to the construction as shown in FIGS. 12 and 13. The signal processing circuit 8 is not exposed to the fluid fuel. Such mold structure can improve the corrosion resistance and durability and further improve the long-term reliability.

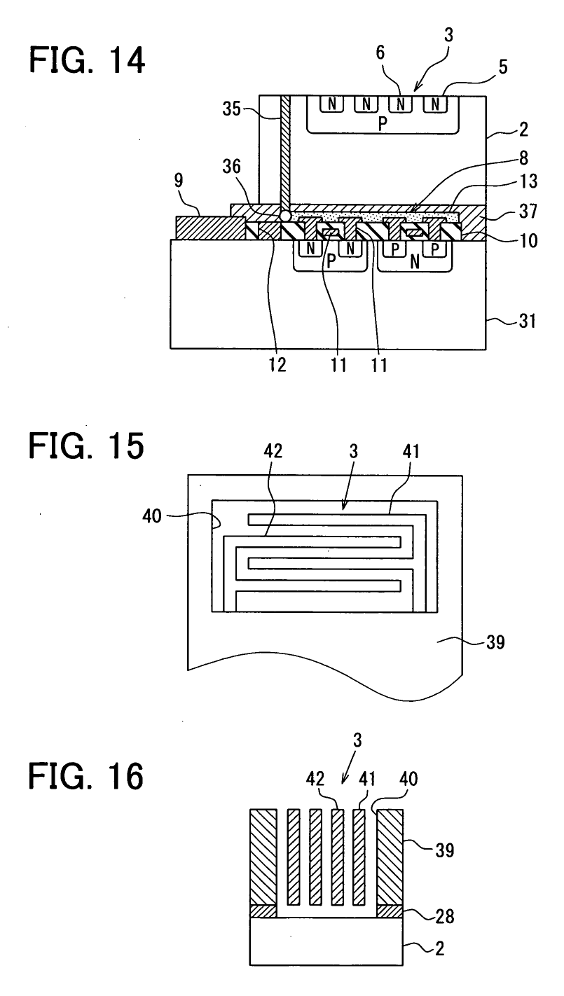

FIG. 14 shows an eleventh embodiment of the invention. The mutually corresponding parts in the eleventh and ninth embodiments are designated by the same reference numerals. The semiconductor substrate 31 is provided with the signal processing circuit 8. The semiconductor substrate 2 is provided with the comb-like electrodes 5 and 6. The eleventh embodiment mounts the semiconductor substrate 2 on the semiconductor substrate 31. A lead-through electrode 35 and a bump 36 are used for connection between the signal processing circuit 8 and the comb-like electrodes 5 and 6. The two semiconductor substrates 2 and 31 are bonded through the intervention of a coating member 37 made of resin etc.

The other portions of the construction according to the eleventh embodiment are the same as the ninth embodiment. Therefore, the eleventh embodiment can provide almost the same effect as the ninth embodiment. In particular, the eleventh embodiment covers the signal processing circuit 8 with the following describes 2. The stack structure can miniaturize the size and protect the circuit. The use of different chips can improve a yield ratio.

FIGS. 15 and 16 show a twelfth embodiment of the invention. The mutually corresponding parts in the twelfth and first embodiments are designated by the same reference numerals. The twelfth embodiment uses the MEMS technology such as reactive ion etching to form comb-like electrodes 41 and 42. In FIG. 15, the vertical size of the comb-like electrodes 41 and 42 is increased to increase facing areas of these electrodes.

Specifically, an insulating film 38 is formed on the top surface of the semiconductor substrate 2 (Si substrate). An Si layer 39 is formed on the insulating film 38. An opening 40 is formed in the insulating film 38 and the Si layer 39. The comb-like electrodes 41 and 42 are provided in the opening 40 so that they are exposed. The opening 40 is sized several hundred micrometers to several millimeters vertically and horizontally. In FIG. 15, the comb-like electrodes 41 and 42 are sized approximately ten micrometers vertically and horizontally. The width of these electrodes is approximately three micrometers (horizontally in FIG. 15). A gap between the electrodes is approximately five micrometers. The MEMS technology can be used to form tens to hundreds of pairs of comb tooth sections 41b and 42b for the comb-like electrodes 41 and 42.

The other portions of the construction according to the twelfth embodiment are the same as the first embodiment. Therefore, the twelfth embodiment can provide almost the same effect as the first embodiment. In particular, the twelfth embodiment can greatly reduce mounting areas of the comb-like electrodes 41 and 42 and further miniaturize the overall construction.

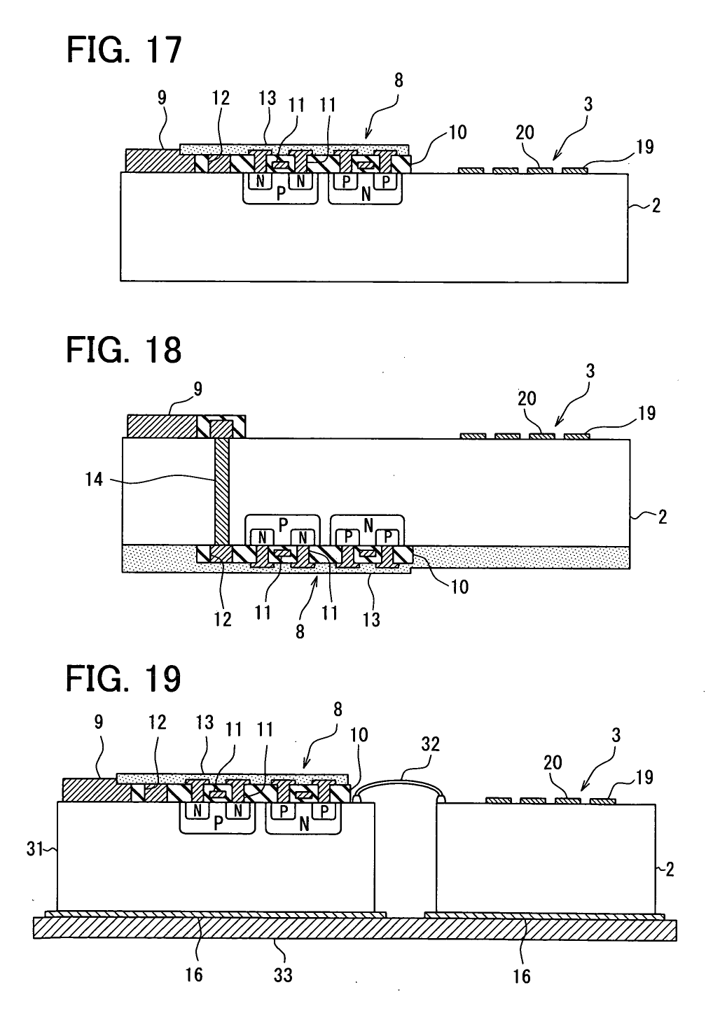

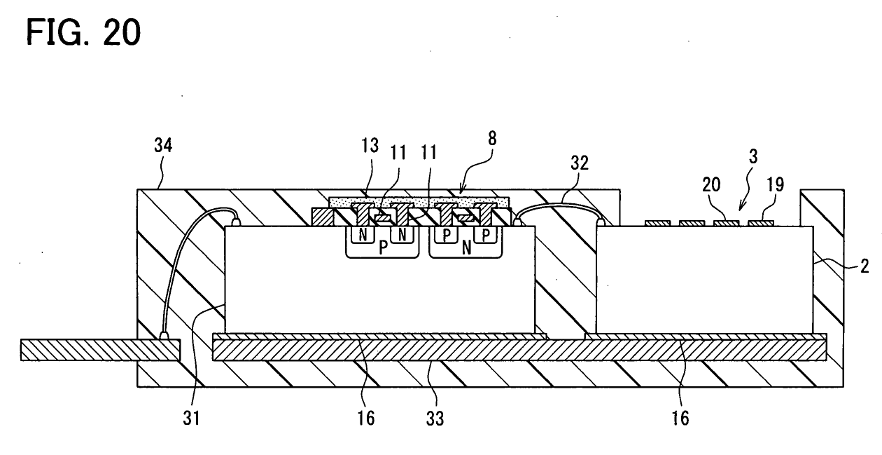

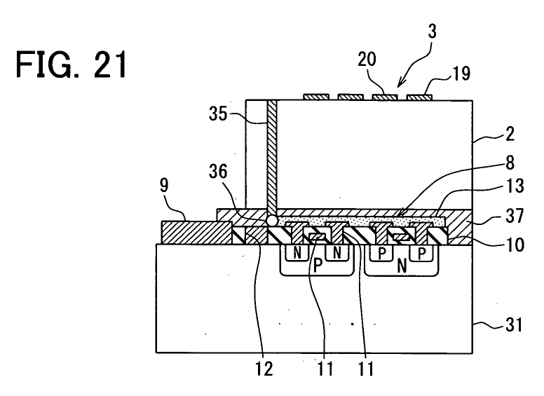

FIGS. 17 through 21 show thirteenth through seventeenth embodiments of the invention. The thirteenth through seventeenth embodiments use the comb-like electrodes 19 and 20 made of corrosion-resisting polysilicon as described in the fourth embodiment to construct the sensor section 3 in the sixth embodiment (see FIG. 8), the eighth embodiment (see FIG. 10), the ninth embodiment (see FIG. 11), the tenth embodiment (see FIG. 12), and the eleventh embodiment (see FIG. 14).

The sensor section 3 uses the comb-like electrodes 19 and 20 made of the corrosion-resisting polysilicon. Since the polysilicon is corrosion resistive to the fluid fuel, the full corrosion resistance can be ensured while the comb-like electrodes 19 and 20 are exposed to the fluid fuel, i.e., no protection film is needed. The sensor can be easily fabricated using a general semiconductor manufacturing process. Manufacturing costs can be further reduced.

While the above-mentioned embodiments are applied to the fluid nature sensor 1 for detecting a blend ratio of the fluid fuel (gasoline and alcohol), the invention is not limited thereto. The invention may be applied to a fluid nature sensor (impedance sensor) for detecting natures of the other fluids. Further, the invention may be applied to an impedance sensor (humidity sensor or gas sensor) for detecting a gas blend ratio (e.g., humidity or gas density).

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A fluid sensor for detecting property of fluid by dipping the sensor in the fluid, the sensor comprising:
a semiconductor substrate; and
a comb-teeth electrode made of a first diffusion layer and disposed on a first surface of the substrate.

2. The fluid sensor according to claim 1, wherein
the comb-teeth electrode includes first and second common portions and a plurality of first and second comb-teeth,
the plurality of first comb-teeth protrudes from the first common portion, and the plurality of second comb-teeth protrudes from the second common portion, and
the first comb-teeth and the second comb-teeth are interleaved by a predetermined distance therebetween.

3. The fluid sensor according to claim 1, further comprising:
a second diffusion layer disposed on at least a part of a second surface of the substrate, wherein
the second surface is opposite to the first surface, and
the part of the second surface corresponds to the comb-teeth electrode.

4. The fluid sensor according to claim 1, further comprising:
a third diffusion layer disposed on the first surface of the substrate, wherein
the third diffusion layer surrounds the comb-teeth electrode.

5. The fluid sensor according to claim 3, further comprising:
a ground electrode disposed on the first surface of the substrate; and
a through-hole electrode disposed in a through hole of the substrate, wherein
the through hole penetrates the substrate from the first surface to the second surface, and
the through-hole electrode electrically couples the ground electrode and the second diffusion layer.

6. The fluid sensor according to claim 3, further comprising:
a metallic film disposed on the second diffusion layer;
a lead frame disposed on the metallic film;
a ground electrode disposed on the first surface of the substrate; and
a bonding wire coupling the lead frame and the ground electrode.

7. The fluid sensor according to claim 1, further comprising:
a signal processing circuit disposed on the substrate.

8. The fluid sensor according to claim 1, wherein
the substrate has an elongated shape.

9. A fluid sensor for detecting property of fluid by dipping the sensor in the fluid, the sensor comprising:
a semiconductor substrate; and
a comb-teeth electrode made of poly silicon and disposed on a first surface of the substrate.

10. An impedance sensor for detecting property of fluid or gas by arranging the sensor in the fluid or the gas, the sensor comprising:
a semiconductor substrate; and
a comb-teeth electrode made of a first diffusion layer and disposed on a first surface of the substrate.

11. The impedance sensor according to claim 10, wherein
the comb-teeth electrode includes first and second common portions and a plurality of first and second comb-teeth,
the plurality of first comb-teeth protrudes from the first common portion, and the plurality of second comb-teeth protrudes from the second common portion, and
the first comb-teeth and the second comb-teeth are interleaved by a predetermined distance therebetween.

12. The impedance sensor according to claim 10, wherein
the comb-teeth electrode is capable of being applied with a predetermined alternating voltage.

13. The impedance sensor according to claim 11, wherein
the substrate includes a P conductive type layer disposed in a surface portion of the first surface of the substrate,
the comb-teeth electrode is disposed in the P conductive type layer,
the comb-teeth electrode has a N conductive type,
a forward bias voltage is applied to the comb-teeth electrode, and
a reverse bias voltage is applied to the P conductive type layer.

14. The impedance sensor according to claim 10, further comprising:
a second diffusion layer disposed on at least a part of a second surface of the substrate, wherein
the second surface is opposite to the first surface, and
the part of the second surface corresponds to the comb-teeth electrode.

15. The impedance sensor according to claim 10, further comprising:
a third diffusion layer disposed on the first surface of the substrate, wherein
the third diffusion layer surrounds the comb-teeth electrode.

16. The impedance sensor according to claim 14, further comprising:
a ground electrode disposed on the first surface of the substrate; and
a through-hole electrode disposed in a through hole of the substrate, wherein
the through hole penetrates the substrate from the first surface to the second surface, and
the through-hole electrode electrically couples the ground electrode and the second diffusion layer.

17. The impedance sensor according to claim 14, further comprising:
a metallic film disposed on the second diffusion layer;
a lead frame disposed on the metallic film;
a ground electrode disposed on the first surface of the substrate; and
a bonding wire coupling the lead frame and the ground electrode.

18. The impedance sensor according to claim 10, further comprising:
a signal processing circuit disposed on the substrate.

19. The impedance sensor according to claim 18, wherein
the signal processing circuit is disposed on a second surface of the substrate, and
the second surface is opposite to the first surface.

20. The impedance sensor according to claim 10, further comprising:
a signal processing circuit disposed on another substrate, wherein
the signal process circuit and the comb-teeth electrode are electrically coupled with a bonding wire.

21. The impedance sensor according to claim 20, wherein
the substrate with the comb-teeth electrode and the other substrate with the signal processing circuit are sealed with a resin mold in such a manner that the comb-teeth electrode is exposed from the resin mold.

22. The impedance sensor according to claim 10, further comprising:
a signal processing circuit disposed on another substrate; and
a through-hole electrode disposed in a through hole of the substrate, wherein
the substrate and the other substrate are bonded with a resin layer,
the through hole penetrates the substrate from the first surface to a second surface,
the second surface is opposite to the first surface,
the through-hole electrode electrically couples the comb-teeth electrode and the signal processing circuit with a bump, and
the bump is disposed between the substrate and the other substrate.

23. The impedance sensor according to claim 11, wherein
the comb-teeth electrode has a MEMS structure,
each of first and second comb-teeth has a thickness, which is perpendicular to the first surface of the substrate, and a width, which is parallel to the first surface of the substrate and perpendicular to a longitudinal direction of the comb-teeth, and
the thickness is larger than the width so that a facing area between the first and second comb-teeth becomes large.

24. An impedance sensor for detecting property of fluid or gas by arranging the sensor in the fluid or the gas, the sensor comprising:
a semiconductor substrate; and
a comb-teeth electrode made of poly silicon and disposed on a first surface of the substrate.

25. The impedance sensor according to claim 24, wherein
the comb-teeth electrode is embedded in a surface portion of the first surface of the substrate.

26. The impedance sensor according to claim 24, wherein
the comb-teeth electrode includes first and second common portions and a plurality of first and second comb-teeth,
the plurality of first comb-teeth protrudes from the first common portion, and the plurality of second comb-teeth protrudes from the second common portion, and
the first comb-teeth and the second comb-teeth are interleaved by a predetermined distance therebetween.

27. The impedance sensor according to claim 24, wherein
the comb-teeth electrode is capable of being applied with a predetermined alternating voltage.

28. The impedance sensor according to claim 24, further comprising:
a second diffusion layer disposed on at least a part of a second surface of the substrate, wherein
the second surface is opposite to the first surface, and
the part of the second surface corresponds to the comb-teeth electrode.

29. The impedance sensor according to claim 24, further comprising:
a third diffusion layer disposed on the first surface of the substrate, wherein
the third diffusion layer surrounds the comb-teeth electrode.

30. The impedance sensor according to claim 28, further comprising:
a ground electrode disposed on the first surface of the substrate; and
a through-hole electrode disposed in a through hole of the substrate, wherein
the through hole penetrates the substrate from the first surface to the second surface, and
the through-hole electrode electrically couples the ground electrode and the second diffusion layer.

31. The impedance sensor according to claim 28, further comprising:
a metallic film disposed on the second diffusion layer;
a lead frame disposed on the metallic film;
a ground electrode disposed on the first surface of the substrate; and
a bonding wire coupling the lead frame and the ground electrode.

32. The impedance sensor according to claim 24, further comprising:
a signal processing circuit disposed on the substrate.

33. The impedance sensor according to claim 32, wherein
the signal processing circuit is disposed on a second surface of the substrate, and
the second surface is opposite to the first surface.

34. The impedance sensor according to claim 24, further comprising:
a signal processing circuit disposed on another substrate, wherein
the signal process circuit and the comb-teeth electrode are electrically coupled with a bonding wire.

35. The impedance sensor according to claim 34, wherein
the substrate with the comb-teeth electrode and the other substrate with the signal processing circuit are sealed with a resin mold in such a manner that the comb-teeth electrode is exposed from the resin mold.

36. The impedance sensor according to claim 24, further comprising:
a signal processing circuit disposed on another substrate; and
a through-hole electrode disposed in a through hole of the substrate, wherein
the substrate and the other substrate are bonded with a resin layer,
the through hole penetrates the substrate from the first surface to a second surface,
the second surface is opposite to the first surface,
the through-hole electrode electrically couples the comb-teeth electrode and the signal processing circuit with a bump, and
the bump is disposed between the substrate and the other substrate.

37. The impedance sensor according to claim 24, wherein
the comb-teeth electrode has a MEMS structure,
each of first and second comb-teeth has a thickness, which is perpendicular to the first surface of the substrate, and a width, which is parallel to the first surface of the substrate and perpendicular to a longitudinal direction of the comb-teeth, and
the thickness is larger than the width so that a facing area between the first and second comb-teeth becomes large.

38. The impedance sensor according to claim 24, wherein
the substrate has an elongated shape.
